(19) United States
(12) Patent Application Publication
(10) Pub. No.: US 2024/0322049 A1
(43) Pub. Date: Sep. 26, 2024

(54) HIGH VOLTAGE DIODES FOR WAFER ON WAFER PACKAGING OF SEMICONDUCTOR DEVICE

(71) Applicant: Micron Technology, Inc., Boise, ID (US)

(72) Inventors: Shyam Surthi, Boise, ID (US); Haitao Liu, Boise, ID (US); Michael A. Smith, Boise, ID (US)

(21) Appl. No.: 18/588,352

(22) Filed: Feb. 27, 2024

Related U.S. Application Data
(60) Provisional application No. 63/453,603, filed on Mar. 21, 2023.

(51) Int. Cl. H01L 29/861; H01L 21/265; H01L 21/768; H01L 23/00; H01L 29/66; H10B 80/00

(52) U.S. Cl. CPC H01L 29/861; H01L 21/265; H01L 21/76898; H01L 24/08; H01L 24/80; H01L 29/6609; H10B 80/00; H01L 2224/08145; H01L 2224/80895; H01L 2224/80896

(57) ABSTRACT

A semiconductor device including a first semiconductor device that includes a substrate, a memory array disposed above the substrate and below a frontside surface of the first semiconductor device, a plurality of source region contact (SRC) nodes disposed under the memory array, and a plurality of high-voltage (HV) diodes disposed in the substrate, each of the plurality of HV diodes being connected to corresponding one of the plurality of SRC nodes; and a second semiconductor device including a plurality of complementary-metal-oxide semiconductor (CMOS) devices, each of the plurality of CMOS devices being connected to, through a backside surface of the second semiconductor device and the frontside surface of the first semiconductor device, corresponding bond pad of the memory array, wherein fusion bonding exists between the backside surface of the second semiconductor device and the frontside surface of the first semiconductor device.

### CROSS-REFERENCE TO RELATED APPLICATION(S)

The present application claims priority to U.S. Provisional Patent Application No. 63/453,603, filed Mar. 21, 2023, the disclosure of which is incorporated herein by reference in its entirety.

### TECHNICAL FIELD

The present disclosure generally relates to high-voltage (HV) diodes, and more particularly relates to HV diodes routed to memory array wafer source region contact (SRC) in wafer-on-wafer (WOW) packaging of semiconductor device.

### BACKGROUND

Fabrication of microelectronic devices such as high-density memory devices generally include bonding a wafer, e.g., a complementary metal-oxide-semiconductor (CMOS) wafer, to a memory array wafer to form the WOW packaging. The CMOS wafer and the memory array wafer can be further mounted on a package substrate or a carrier wafer and encased in a protective covering. The CMOS wafer may include integrated circuitry with a high density of very small components including processor circuits, imager devices, string drivers, and/or high voltage (HV) circuits. On the other hand, the memory array wafer may include memory arrays including NAND flash memory arrays, dynamic random-access memory (DRAM) arrays, and/or phase change memory (PCM) arrays, the memory arrays being connected to the HV circuits of the CMOS wafer for data signal and control signal transition. Conventional processes for bonding the CMOS wafer and the memory array wafer include electrically coupling/routing of SRC nodes of the memory array to HV diodes that are capable of withstanding high operation voltages.

### BRIEF DESCRIPTION OF THE DRAWINGS

FIG. 1 depicts a schematic view of a semiconductor device including HV diodes routed to memory array SRC nodes in accordance with embodiments of the present technology.

FIGS. 2A through 2E illustrate stages of processing a memory device for forming HV diodes in semiconductor device according to embodiments of the present technology.

FIG. 3 depicts a schematic view of another memory device having HV diodes according to embodiments of the present technology.

FIG. 4 depicts a schematic view of another memory device having HV diodes with different configurations according to embodiments of the present technology.

FIG. 5 is a flow chart illustrating a method of processing HV diodes in a memory device for semiconductor device fabrication according to embodiments of the present technology.

FIG. 6 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

High density memory devices such as NAND flash memory utilizes WOW bonding scheme, e.g., bonding a memory array wafer to a CMOS wafer, in order to achieve a higher device packaging density and improved performance of the components separately processed in the memory array wafer and the CMOS wafer. In fabrications of traditional NAND flash memory such as CMOS on Array (CuA) scheme, the SRC nodes of the memory array are routed to corresponding HV diodes which are capable of withstanding high operation voltages close to or higher than 30V. Particularly, HV diodes in the CuA fabrication scheme are generally disposed in a substrate of the CMOS wafer and are routed to the SRC nodes of the memory array through multiple metal routing layers disposed between the substrate and the memory array. The HV diodes, however, might be hard to be implemented into the CMOS wafer substrate for WOW bonding schemes including a face-to-face (F2F) WOW hybrid bonding scheme and a face-to-back (F2B) direct bonding scheme. The processing of HV diodes in CMOS wafer substrate for above noted WOW bonding schemes can be complicated and the additional routings in the CMOS wafer may degrade the packaging density and device performance thereon.

In addition, charges included by plasma-based semiconductor processes may be accumulated on the memory device during the fabrication of the high-density memory devices (e.g., a high bias etching process to form memory pillars). The accumulated charges need to be dissipated through a low resistance path to prevent arcing on the memory wafers and damaging of processing tools.

To address the above-described challenges and others, the present technology includes a novel process of fabricating HV diodes in the memory array wafer for the WOW bonding in semiconductor device fabrication. In particular, HV diodes including a heavily doped region and a lightly doped region can be formed in a substrate of the memory array wafer. The HV diodes can be directly routed to SRC nodes of the memory array through contacts disposed there between. Conventional semiconductor process such as i-line lithography can be utilized to fabricate the HV diodes in the memory array wafer, therefore maintaining a low manufacturing cost. Moreover, the HV diodes described in the present technology offer a break down voltage tunability through adjusting a resist layer trimming process which in turn affects junction grading within the HV diodes. Further, the fabrication of HV diodes in the memory array wafer avoids complex routing in the CMOS wafer and provides flexibilities in the locations and numbers of HV diodes corresponding to the SRC nodes of the memory array.

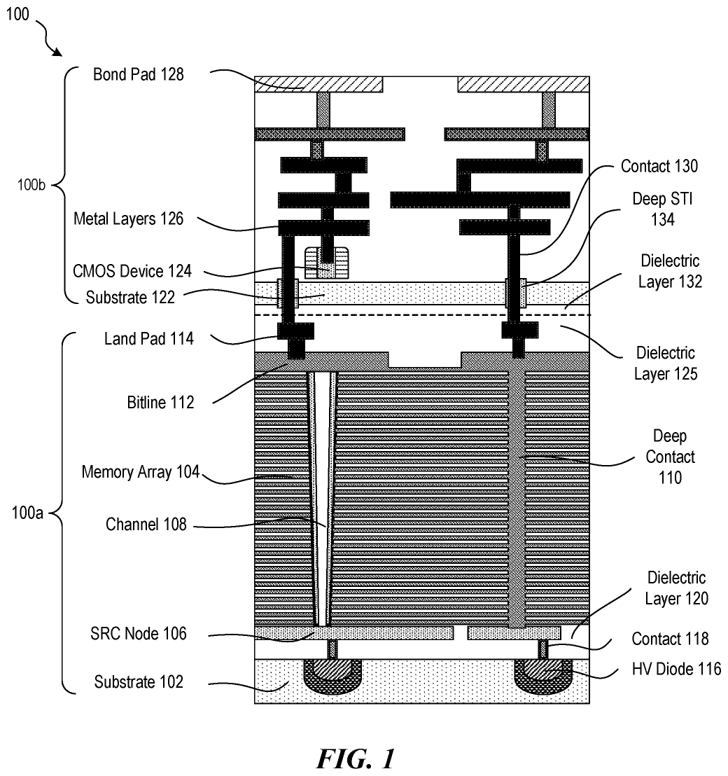

FIG. 1 depicts a schematic view of a semiconductor device 100 including HV diodes routed to memory array SRC nodes 106 in accordance with embodiments of the present technology. The semiconductor device 100 includes a memory device 100a and a logic device 100b, the logic device 100b being bonded to the memory device 100a. Specifically, in this semiconductor device 100, a backside surface of the Logic device 100b is bonded to a frontside surface of the memory device 100a through a direct WOW bonding technique, e.g., a dielectric-dielectric fusion bonding with strong covalent bonds, to form a F2B WOW bonding.

In this example, the logic device 100b may include a substrate 122, a plurality of CMOS devices 124 that is disposed within or above the substrate 122, a plurality of metal routing layers 126, and a plurality of bond pads 128 disposed on a frontside surface of the logic device 100b. The logic device 100b further includes a plurality of deep shallow trench isolation (STI) regions 134 disposed within the substrate 122, and a plurality of contacts 130. Each of the plurality of contacts 130 connects to corresponding one or more of the plurality of metal routing layers 126 and passes through corresponding one of the plurality of deep STI regions 134 for signal transition.

On the other hand, the memory device 100a may include a substrate 102, a memory array 104 disposed above the substrate 102, a plurality of channels 108 and a plurality of deep contacts 110 vertically extending through the memory array 104, and a plurality of land pads 114 each being connected to corresponding one of the plurality of bitlines 112 or deep contacts 110. In this example, each of the plurality of channels 108 connects memory strings from a top tier and a bottom tier. Further, each of the plurality of contacts 130 is connected to corresponding land pads 114 of the memory device 100a, transmitting data/control signals between the CMOS devices 124 and the memory array 104. The memory device 100a includes bitline 112 disposed above the memory array 104. In addition, the logic device 100b and the memory device 100a includes a dielectric layer 132 and a dielectric layer 125 that are disposed on their backside surface and frontside surface, respectively. Here, the dielectric layers 132 and 125 provide electric isolation among the components disposed in the backside of the logic device 100b and the frontside of the memory device 100a. Further, the direct bonding interface between the logic device 100b and the memory device 100a can be formed by bonding the dielectric layers 132 and 125, including applying heat or compressive pressures there between to form dielectric-dielectric fusion bonds. In this example, the dielectric layers 132 and 125 can be made of materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Moreover, the fusion bonds formed at the interface of the logic device 100b and the memory device 100a can be oxide-oxide covalent bonds.

In this WOW bonding scheme of semiconductor device 100, the memory device 100a further includes a plurality of HV diodes 116 that are routed to the memory array 104 for SRC nodes protection. As shown in FIG. 1, the plurality of HV diodes 116 can be disposed in the substrate 102, e.g., under a frontside surface of the substrate 102. Each of the plurality of HV diodes 116 is connected to a corresponding SRC node 106 of the memory array 104 through the contact 118. The memory device 100a also includes a dielectric layer 120 disposed between the SRC nodes 106 and the substrate 102, providing electrical isolation there between. In this example, each of the SRC nodes 106 of the memory array 104 may have/be connected to one or more dedicated HV diodes 116.

The semiconductor device 100 shown in this example enables transitions of signal/data signals in high voltages from the CMOS devices 124 to corresponding SRC node 106 of the memory array 104. Specifically, the configuration of the HV diodes 116, i.e., disposing in the substrate 102 of the memory array 104 and being directly connected to corresponding SRC nodes 106, avoids complex routing to the logic device 100b in the WOW packaging 100. In addition, the HV diodes 116 can withstand a high voltage, e.g., close to or higher than 30V, to effectively protect the SRC nodes 106 in the WOW bonding scheme 100. In this example, the plurality of HV diodes 116 as well as the plurality of SRC nodes 106 are disposed closer to the memory array 104 than to the fusion bonding interface.

In some other examples, the HV diodes can be implemented and routed to SRC nodes of memory array wafer in a WOW bonding scheme. For example, in a WOW bonding scheme having a front side surface of a CMOS wafer bonded to a frontside surface of a memory array wafer, i.e., a F2F WOW bonding, HV diodes can be fabricated into a substrate of the memory array wafer. In this example, the HV diodes can be directly connected to SRC nodes of the memory array to provide a protection under a high voltage close to or higher than 30V.

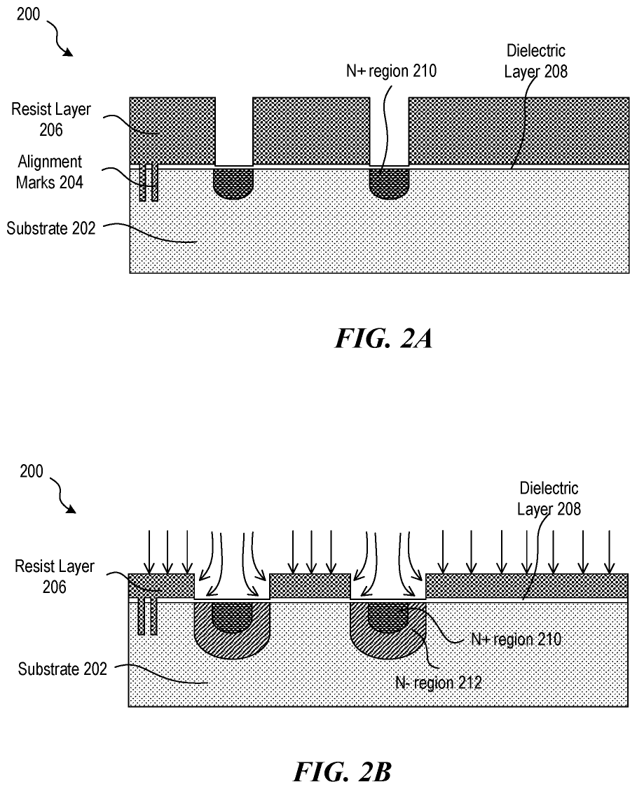

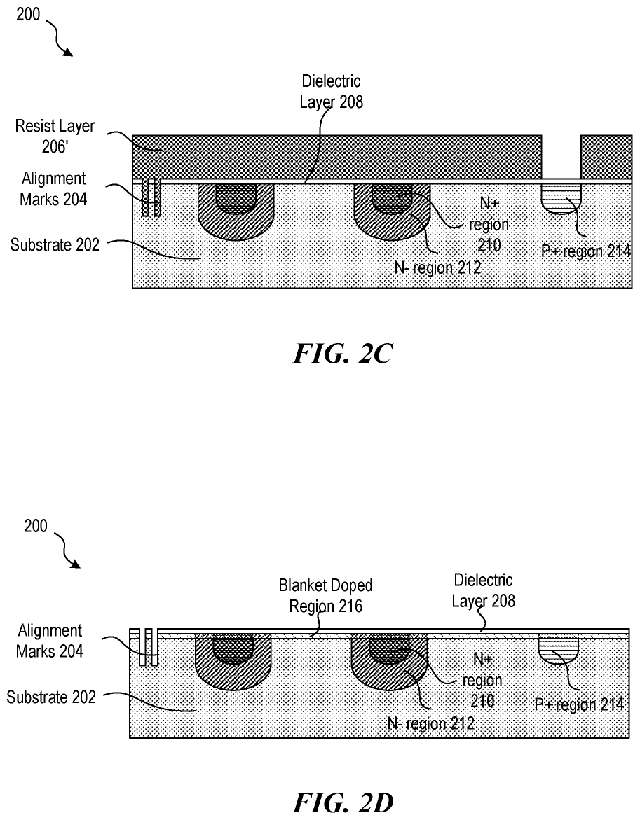

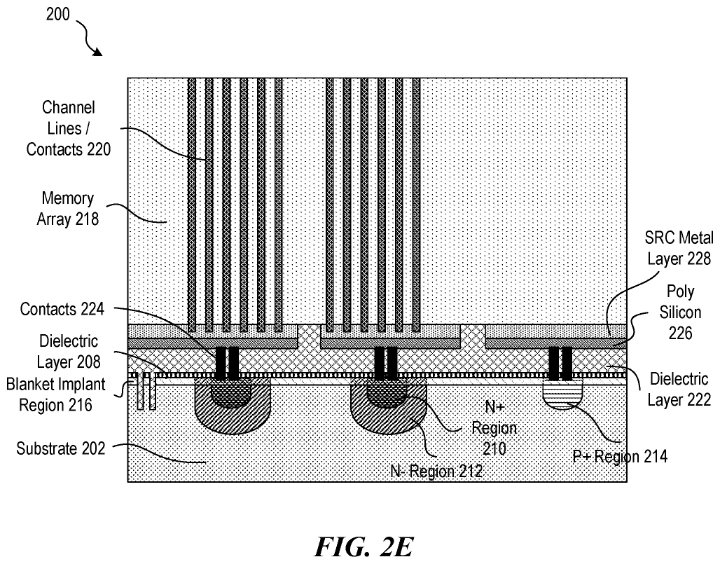

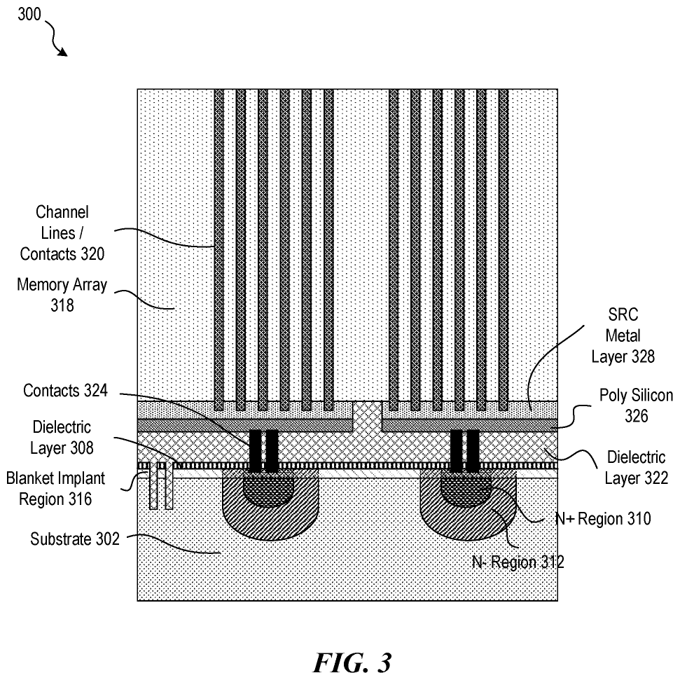

In this semiconductor device assembly 100, each of the logic device 100b and the memory device 100a can be processed separately. Particularly, the plurality of HV diodes 116 can be fabricated during the processes of the memory device 100a, before it is bonded with the Logic device 100b. FIGS. 2A through 2E illustrate stages of processing a memory device 200 including forming HV diodes for WOW bonding of semiconductor devices in accordance with embodiments of the present technology. For example, FIG. 2A illustrates the memory device 200 after forming a plurality of heavily doped regions 210. As shown, the memory device 200 includes a substrate 202 which can be made of single crystal silicon and may contains a low level of P type dopants such as boron or gallium. A dielectric layer 208 is disposed above a frontside surface of the substrate 202. The dielectric layer 208 can be made of silicon oxide or silicon nitride, and performs as a sacrificial layer thereon. Here, a proper thin film deposition technique including chemical vapor deposition, physical vapor deposition, atomic layer deposition, plating, electroless plating, spin coating, and/or other suitable techniques can be utilized to deposit the dielectric layer 208. In another example, a thermal or plasma oxidation process can be used to process a silicon oxide film of the dielectric layer 208. Moreover, a thermal or plasma nitridation process can be used to process a silicon nitride film of the dielectric layer 208. The dielectric layer 208 may have a thickness ranging from 1 nm to 5 nm. Once the dielectric layer 208 is formed, one or more alignment marks 204 can be patterned from the frontside surface of the dielectric layer 208 and to extend into the substrate 202. The alignment marks 204 may have various shapes and are configured to align the memory device 200 to one or more photomasks in the fabrication processes.

In this example, the memory device 200 further includes a photo resist layer 206, which is deposited above and patterned to form openings to expose a plurality of regions of the dielectric layer 208. The resist layer 206 can be patterned using various optical lithography techniques, e.g., an i-line light with wavelengths of 365 nm or a deep ultraviolet (DUV) light with wavelengths of 193 nm or 157 nm, which allow minimum feature sizes down to 25 nm. The patterned openings of the photo resist layer 206 may have various shapes along a horizontal plane, including a circular shape, an oval shape, a square shape, and/or a rectangular shape. Here, the resist layer 206 may have a thickness ranging from 100 nm to 500 nm. The patterned openings may have a width and a length ranging from 25 nm to 50000 nm.

An ion implantation process can be further conducted, through the patterned openings of photo resist layer 206, on the memory device 200 to form the plurality of heavily doped regions 210 shown in FIG. 2A. In this example, a N type dopant material such as phosphorus, arsenic, and/or antimony can be introduced into the substrate 202 of the memory device 200. This ion implantation process can offer optimal precision and dopant profile control. For example, a rectangular doping profile (with an arc bottom from a side view) can be formed, under the frontside surface of the substrate 202, using 30 KeV phosphorus ions at room temperature (e.g., close to 300K) to fluences close to 3×10²⁰ ions·cm⁻². Alternatively, the heavily doped regions 210 can be formed in a square shape. In this example, each of the heavily doped regions 210 may have a width and a length similar to the openings of patterned resist layer 206 and ranging from 100 nm to 2000 nm, and a depth ranging from 50 nm to 100 nm. In some other examples, the width and length of each of the heavily doped regions 210 may be ranging from 25 nm to 50000 nm. In some other examples, the ion implantation process may implant P type dopant material such as Boron and/or Gallium into a N type doped substrate 202 and form the plurality of P type heavily doped regions. Further, the location of the plurality of heavily doped regions 210 may vary in the memory device 200. For example, the plurality of heavily doped regions 210 may be fabricated at various areas across the memory array plane and memory dies, including the memory plane edges.

FIG. 2B illustrates the memory device 200 after forming a plurality of lightly doped regions 212. Once the heavily doped regions 210 are formed, an trimming process can be applied on the resist layer 206. The trimming process may be isotropic or anisotropic, e.g., having a etch rate on top of the openings higher than that on sidewall of the openings. The arrows in this FIG. 2B illustrate the etchant chemicals approaching to the resist layer 206 openings. This trimming process may etch the patterned resisted layer conformally, e.g., equally enlarging the plurality of openings and reducing the thickness of the patterned resist layer 206. In another example, an anisotropic trimming process (e.g., pseudo conformal etching) can be conducted by utilizing a low bias chemical etching technique, e.g., removing the thickness of the patterned resist layer 206 faster than etching the sidewall of the patterned openings. This trimming process, as shown in FIG. 2B, enlarges the plurality of resist layer 206 openings for a following ion implantation process to form the lightly doped regions 212. Here, each of the openings may have a width and a length that are enlarged for a range from 200 nm to 1000 nm, or from 25 nm to 10000 nm. In addition, the following ion implantation process may implant a same type of dopant material to the heavily doped regions 210. For example, 60 KeV phosphorus ions at room temperature (e.g., close to 300K) to fluences close to 1×10¹⁶ ions·cm⁻² can be implanted into the substrate 202 through the enlarged openings to form the N type lightly doped regions 212, in accordance with the N type heavily doped regions 210. The lightly doped regions 212 may also have a similar doping profile to the heavily doped regions 210, such as a square shape or a rectangular shape within the substrate 202. In this example, each of the lightly doped regions 212 that surrounds corresponding heavily doped regions may have a width and a length ranging from 200 nm to 1000 nm or from 25 nm to 10000 nm, and a depth ranging from 300 nm to 500 nm.

In this example, the combined heavily doped regions 210 and lightly doped regions 212 form the plurality of HV diodes in the memory device 200. As shown in FIG. 2B, each of the plurality of heavily doped regions 210 is surrounded by corresponding one of the plurality of lightly doped regions 212, both are disposed underneath the frontside surface of the substrate 202 of the memory device 200. In one example, the HV diodes each includes a N+N− junction through which the HV diodes withstand a high reverse voltage, e.g., close to or higher than 30V, which is applied to the heavily doped N+ region 210 (or relative to the lightly doped N− region 212). The HV diodes each acts as a normal rectifier with normal forward voltage and reverse voltage before it reaches a certain value (e.g., a Zener voltage or an avalanche voltage) and break down. Here, a control on the width and depth of each of the plurality of lightly doped regions 212 is critical for the HV diodes junction grading and to ensure a needed minimum break down voltage, which can be achieved by adjusting the lateral trimming of the openings of the resist layer 206 and acceleration voltages of the ion implantation process for the lightly doped regions 212, respectively.

There may be a minimum distance required between adjacent HV diodes, i.e., a threshold distance between adjacent edges of lightly doped regions 212. The HV diodes may need to be separated in the memory device 200 to prevent punch through at a higher working voltage. For example, the lightly doped regions 212 each having a doping level close to 1×10¹⁶ ions·cm⁻² may need to keep a lateral distance close to or larger than 2 μm in order to avoid punch through conduction therebetween at an applied voltage of 15V at room temperature.

The memory device 200, as shown in FIG. 2C, may also include another heavily doped region 214. For example, a dopant material having an opposite type of doping to the heavily and lightly doped regions 210 and 212 can be implanted into the substrate 202 to form the heavily doped regions 214. Specifically, once the N type heavily doped region 210 and N type lightly doped region 214 are formed, P type dopant materials such as boron and/or gallium can be implanted accordingly. The heavily doped P type regions 214 can be disposed in the P type doped substrate 202 to provide an improved contact/lower contact resistance for deep contacts passing through memory array of the memory device 200. In one example, boron ions with a doping level close to 2×10²⁰ ions·cm⁻² can be implanted and form the plurality of heavily doped region 214. In this example, the ion implantation process can be conducted after stripping off the patterned resist layer 206 and applying another resist layer 206′. As shown, the resist layer 206′ can be further patterned to form openings to expose regions of the dielectric layer 208 other than the plurality of heavily doped and lightly doped regions 210 and 212. Here, a minimum distance from the opening edge of the resist layer 206′ to adjacent lightly doped region 212 may be needed, e.g., close to or larger than 1.5 μm. In this example, the location of the plurality of heavily doped regions 214 may vary. For example, they can be disposed toward to the memory array plane edges or distributed throughout the memory array plane. The patterned openings of the photo resist layer 206′ may have various shapes along the horizontal plane, including a circular shape, an oval shape, a square shape, and/or a rectangular shape. Here, the patterned openings of the resist layer 206′ may be ranging from 100 nm to 2000 nm or from 25 nm to 50000 nm.

FIG. 2D illustrates the memory device 200 after forming a blanket doped region 216 underneath the frontside surface of the substrate 202. For example, after forming the heavily doped regions 214, the patterned resist layer 206′ can be stripped off. In addition, a blanket compensatory implantation, e.g., doping boron ions with a low acceleration voltage close to 10 KeV and a low dose level close to 5×10¹¹ ions·cm⁻², can be conducted above the substrate 202. Here, the blanket doped region 216 is configured to mitigate dielectric (e.g., silicon oxide in the dielectric layer 208) fixed charge impact on the break down voltage of the HV diodes formed in the memory device 200. By implementing a pillar doping with dopant opposite to the doped regions 210 and 212 (e.g., blanket doping of boron into the memory array wafer having N+N-junction of HV diodes), a resulting charge imbalance degradation in this example can be compensated to maintain a required HV diodes breakdown voltage, e.g., close to or higher than 30V. In another example, the blanket doped region 216 can be formed before forming the HV diodes and the heavily doped regions 214.

Now turning to FIG. 2E which illustrates the memory device 200 after fabricating the memory array 218. As shown, a dielectric layer 222 can be deposited on the substrate 202 and above the dielectric layer 208. The dielectric layer 222 can cover a whole frontside surface of the substrate 202 and be made of silicon oxide or silicon nitride. Moreover, the dielectric layer 222 may be etched to form one or more contact holes disposed above each of the HV diodes and specifically the plurality of heavily doped regions 214 of the memory device 200. In particular, the contact holes pass through the dielectric layers 222 and 208. Conductive materials such as tungsten or copper can be filled into the contact holes to form the contacts 224, each of which having one end connected to the corresponding heavily doped region 210 of corresponding one of the plurality of HV diodes. In following procedures, a memory array 218 can be fabricated above the dielectric layer 222. For example, the SRC nodes each including a metal layer 228 and a poly silicon layer 226 can be formed above the dielectric layer 222. The poly silicon layer 226 of each of the SRC nodes of the memory array 218 can be disposed below the corresponding SRC metal layer 228 and is connected to another end of corresponding one or more contacts 224. The memory array 218 can be further fabricated above the plurality of SRC nodes and have the channel lines or contacts 220 vertically passing there through. In this example, one or more HV diodes can be configured to connect to one corresponding SRC node of the memory array 218. For example, FIG. 2E provides a scenario of 1:1 matching between the HV diodes and corresponding SRC nodes in the memory device 200. In some other examples, an individual HV diode can be configured to connect to multiple SRC nodes of the memory array 218.

In this example and to form a WOW bonding scheme similar to that of the FIG. 1, the memory device 200 can be further processed to form an additional dielectric layer (not shown) on its frontside surface. The memory device 200 can be further bonded to a CMOS wafer, e.g., the logic device 100b shown in FIG. 1, so as to form a F2B WOW bonding using a direct fusion bonding technique. In this WOW bonding scheme, the HV diodes shown in FIG. 2E can be disposed in the substrate 202 of the memory array wafer, having a direct contact to corresponding SRC nodes to provide protection of high break down voltage close to or higher than 30V.

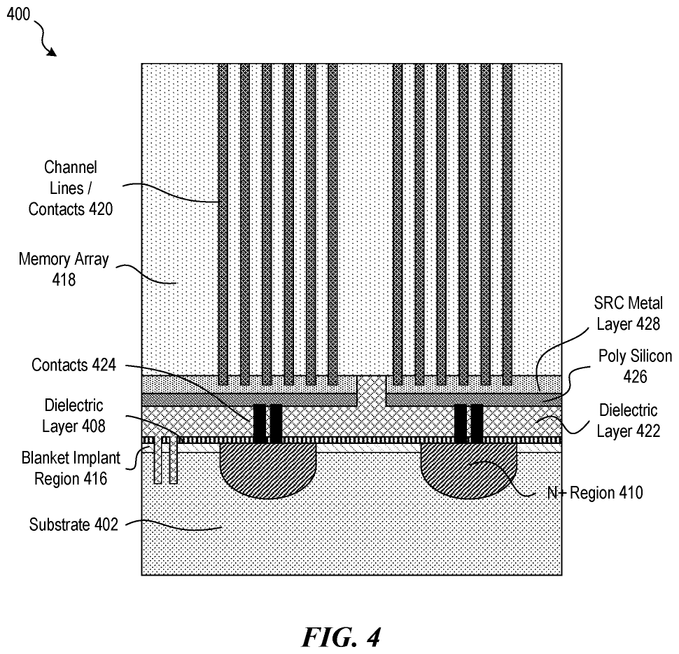

FIG. 3 depicts a schematic view of another memory device 300 having HV diodes according to embodiments of the present technology. In this example, the memory device 300 has a plurality of HV diodes each including a heavily doped region 310 and a lightly doped region 312. The heavily and lightly doped regions 310 and 312 can be made of dopants compensatory to the substrate. For example, n type dopant materials such as phosphorus, arsenic, and/or antimony can be implanted into a p type lightly doped substrate 302 to form the doped regions 310 and 312 of the HV diodes. In this example, each of the SRC nodes of the memory array 318 is connected to one or more HV diodes for a high operation voltage protection. Alternatively, each one of the HV diodes shown in FIG. 3 can be connected to multiple SRC nodes of the memory array 318. The plurality of HV diodes can be fabricated similar to the proceedings described in FIGS. 2A and 2B. Once the HV diodes are completed, a dielectric layer 322 can be deposited on the frontside surface of the substrate 302. The dielectric layer 322 can be further patterned to form contact holes which can be filled by conductive materials to form the contacts 324. As shown the contacts 324 connect the HV diodes, e.g., the heavily doped regions 310 of the HV diodes, to corresponding SRC nodes. Similar to the memory device 200, each of the SRC nodes of the memory device 300 includes a metal layer 328 and a poly silicon layer disposed below the metal layer 328.

In another example, the HV diodes in a memory array device 400 for WOW bonding scheme may only include a highly doped region. For example, FIG. 4 depicts a schematic view of another memory array device 400 having HV diodes according to embodiments of the present technology. Particularly, each of the HV diodes included in the memory array wafer only includes a highly doped region 410 which is made of compensatory dopant to the substrate, e.g., a n type doped region 410 in a p type doped substrate 402. In this example, the N+P− junction is formed at the edge of the heavily doped region 410 to provide a withstanding of high reverse voltage. Similar to the memory array devices 200 and 300, each of the HV diodes of the memory array device 400 can be connected, through the contacts 424, to corresponding one or more SRC nodes of the memory array 418. In another example, each of the SRC nodes of the memory array 418 can be connected to multiple HV diodes of the memory array device 400 for high operation voltage protection.

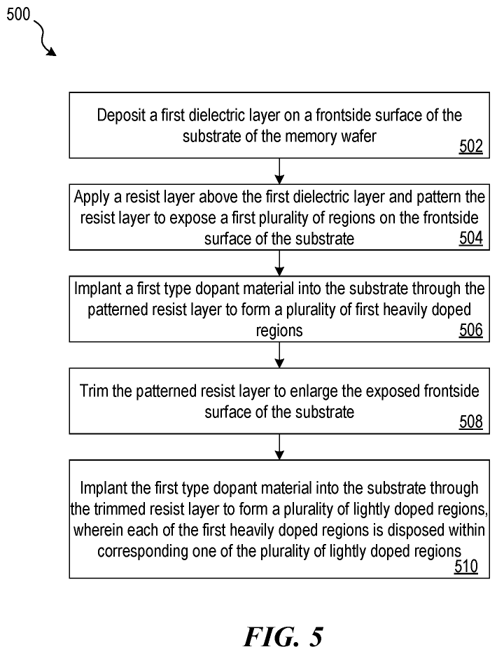

FIG. 5 is a flow chart illustrating a method 500 for processing HV diodes in a memory device for semiconductor device fabrication according to embodiments of the present technology. For example, the method 500 includes depositing a first dielectric layer on a frontside surface of the substrate of the first semiconductor device, at 502. For example, the dielectric layer 208 can be deposited on the frontside surface of the substrate 202 of the memory device 200, as shown in FIG. 2A.

The method 500 also includes applying a resist layer above the first dielectric layer and patterning the resist layer to expose a first plurality of regions on the frontside surface of the substrate, at 504. For example, the resist layer 206 can be deposited above the dielectric layer 208 and patterned. The patterned resist layer 206 can include openings exposing regions of the dielectric layers 208 that correspond to the heavily doped regions 210 of the HV diodes.

In addition, the method 500 includes implanting a first type dopant material into the substrate through the patterned resist layer to form a plurality of first heavily doped regions, at 506. For example, N type dopant materials such as phosphorus ions can be implanted, through the openings of patterned resist layer 206, into the substrate 202 to form the heavily doped regions 210.

Further, the method 500 includes trimming the patterned resist layer to enlarge the exposed frontside surface of the substrate, at 508. For example, an isotropic or anisotropic etching process can be used to trim the patterned resist layer 206, enlarging the openings in the horizontal direction.

Lastly, the method 500 includes implanting the first type dopant material into the substrate through the trimmed resist layer to form a plurality of lightly doped regions, wherein each of the first heavily doped regions is disposed within corresponding one of the plurality of lightly doped regions, at 510. For example, once the patterned resist layer 206 is further trimmed, the ion implantation process can be conducted again to implant phosphorus ions, with an acceleration voltage higher than the implanting of heavily doped regions 210, into the substrate through the enlarged openings of the resist layer 206 to form the lightly doped regions 212. As shown in FIG. 2B, the phosphorus dopant can be implanted deeper into the substrate 202 with a lower doping level, the heavily doped regions 210 being embedded in the lightly doped regions 212, respectively.

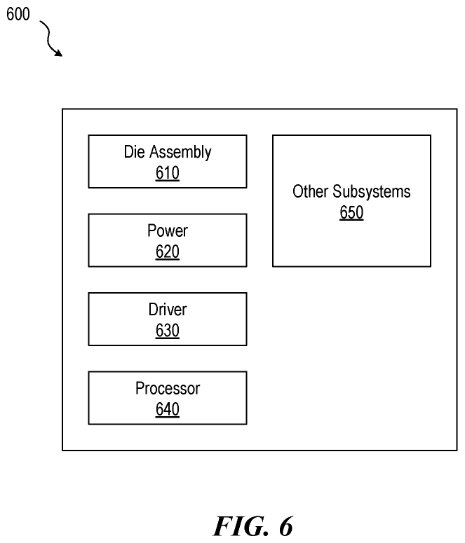

Any one of the semiconductor structures described above with reference to FIGS. 1-4 can be incorporated into any of a myriad of larger and/or more complex systems, a representative example of which is system 600 shown schematically in FIG. 6. The system 600 can include a semiconductor device 610, a power source 620, a driver 630, a processor 640, and/or other subsystems or components 650. The semiconductor device 610 can include features generally similar to those of the semiconductor devices described above and can therefore include HV diodes described in the present technology. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, and appliances. Components of the system 600 may be housed in a single unit or distributed over multiple, interconnected units (e.g., through a communications network). The components of the system 600 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a first semiconductor device, including:
a substrate,
a memory array disposed above the substrate and below a frontside surface of the first semiconductor device,
a plurality of source region contact (SRC) nodes disposed under the memory array, and
a plurality of high-voltage (HV) diodes disposed in the substrate, each of the plurality of HV diodes being connected to corresponding one of the plurality of SRC nodes; and
a second semiconductor device including a plurality of complementary-metal-oxide semiconductor (CMOS) devices, each of the plurality of CMOS devices being connected to, through a backside surface of the second semiconductor device and the frontside surface of the first semiconductor device, corresponding bond pad of the memory array,
wherein fusion bonding exists between the backside surface of the second semiconductor device and the frontside surface of the first semiconductor device.

2. The semiconductor device of claim 1, wherein each of the plurality of HV diodes comprises a lightly doped region disposed under a frontside surface of the substrate of the first semiconductor device and a heavily doped region disposed within the lightly doped region.

3. The semiconductor device of claim 2, wherein the heavily doped region of each of the plurality of HV diodes is disposed under the frontside surface of the substrate of the first semiconductor device.

4. The semiconductor device of claim 2, wherein the lightly doped region and the heavily doped region of each of the plurality of HV diodes comprises N type dopant materials including Phosphorus, Arsenic, and/or Antimony.

5. The semiconductor device of claim 4, further comprising a plurality of P type heavily doped regions disposed in the substrate of the first semiconductor device, wherein the plurality of P type heavily doped regions comprise P type dopant materials including Boron and/or Gallium.

6. The semiconductor device of claim 4, further comprising a lightly doped layer region disposed under the frontside surface of the substrate, wherein the lightly doped layer region comprises P type dopant materials including Boron and/or Gallium.

7. The semiconductor device of claim 2, further comprising a dielectric layer disposed above the substrate and under the plurality of SRC nodes; and a plurality of interconnection contacts connecting the plurality of HV diodes to corresponding SRC nodes, wherein the plurality of interconnection contacts pass through the dielectric layer.

8. The semiconductor device of claim 7, wherein each of the plurality of SRC nodes comprises a metal layer and a poly silicon layer that is disposed under the metal layer, and wherein the plurality of interconnection contacts are respectively connected to the metal layers of the plurality of SRC nodes.

9. The semiconductor device of claim 8, wherein each of the plurality of interconnection contacts is connected to the heavily doped region of corresponding one of the plurality of HV diodes.

10. The semiconductor device of claim 2,
wherein the heavily doped region of each of the plurality of HV diodes has a depth ranging from 50 nm to 100 nm, and a width and a length ranging from 100 nm to 2000 nm or from 25 nm to 50000 nm, and
wherein the lightly doped region of each of the plurality of HV diodes has a depth ranging from 300 nm to 500 nm, and a width and a length ranging from 200 nm to 1000 nm or from 25 nm to 10000 nm.

11. The semiconductor device of claim 1, wherein each of the plurality of HV diodes comprises a heavily doped region that is disposed under a frontside surface of the substrate of the first semiconductor device, and wherein the heavily doped region of each of the plurality of HV diodes comprises N type dopant materials including Phosphorus, Arsenic, and/or Antimony.

12. A semiconductor device, comprising:
a first semiconductor device including a memory array, a plurality of source region contact (SRC) nodes disposed under the memory array, and a plurality of high-voltage (HV) diodes disposed between the plurality of SRC nodes and a backside surface of the first semiconductor device;
a second semiconductor device including a plurality of complementary-metal-oxide semiconductor (CMOS) devices; and
a fusion bonding interface between a frontside surface of the first semiconductor device and a backside surface of the second semiconductor device,
wherein the plurality of SRC nodes are disposed closer to the memory array than to the fusion bonding interface.

13. The semiconductor device of claim 12, wherein the plurality of HV diodes of the first semiconductor device are connected, through the plurality of SRC nodes and the fusion bonding interface, to corresponding CMOS devices of the second semiconductor device.

14. The semiconductor device of claim 13, wherein each of the plurality of HV diodes of the first semiconductor device comprises a N type lightly doped region disposed under corresponding one of the plurality of SRC nodes, and a N type heavily doped region disposed within the N type lightly doped region.

15. The semiconductor device of claim 14, further comprising a plurality of P type heavily doped regions disposed between the plurality of SRC nodes and the backside surface of the first semiconductor device, wherein the plurality of P type heavily doped regions comprise dopant materials including Boron and/or Gallium.

16. A method of forming a semiconductor device, comprising:
forming a memory wafer including a substrate, a memory array disposed between the substrate and a frontside surface of the memory wafer, a plurality of source region contact (SRC) nodes disposed under the memory array, and a plurality of high-voltage (HV) diodes disposed in the substrate;
forming a complementary metal-oxide-semiconductor (CMOS) wafer having a plurality of CMOS devices;
fusion bonding a backside surface of the CMOS wafer to a frontside surface of the memory wafer; and
forming through-wafer interconnects that pass through the CMOS wafer and into the memory wafer, the through-wafer interconnects connecting the plurality of CMOS devices to corresponding land pads of the memory wafer,
wherein the plurality of CMOS devices are electrically coupled to corresponding HV diodes through the through wafer interconnects and the plurality of SRC nodes.

17. The method of forming the semiconductor device of claim 16, wherein forming the memory wafer comprises:
depositing a first dielectric layer on a frontside surface of the substrate of the memory wafer,
applying a resist layer above the first dielectric layer and patterning the resist layer to expose a first plurality of regions on the frontside surface of the substrate,
implanting a first type dopant material into the substrate through the patterned resist layer to form a plurality of first heavily doped regions,
trimming the patterned resist layer to enlarge the exposed frontside surface of the substrate, and
implanting the first type dopant material into the substrate through the trimmed resist layer to form a plurality of lightly doped regions, wherein each of the first heavily doped regions is disposed within corresponding one of the plurality of lightly doped regions.

18. The method of forming the semiconductor device of claim 17, wherein preparing the memory wafer further comprises:
stripping off the trimmed resist layer,
applying another resist layer above the dielectric layer and patterning the another resist layer to expose a second plurality of regions on the frontside surface of the substrate, and
implanting a second type dopant material into the substrate through the patterned another resist layer to form a plurality of second heavily doped regions.

19. The method of forming the semiconductor device of claim 18, wherein preparing the memory wafer further comprises:
depositing a second dielectric layer on the frontside surface of the substrate,
patterning the second dielectric layer and forming interconnection contacts in the patterned second dielectric layer, and
forming the memory array including the plurality of SRC nodes, wherein each of the interconnection contacts is connected to corresponding one of the plurality of SRC nodes.

20. The method of forming the semiconductor device of claim 16, further comprising forming a lightly doped layer region that is disposed under the frontside surface of the substrate of the memory wafer, wherein the lightly doped layer region comprises P type dopant materials including Boron and/or Gallium, and wherein the lightly doped layer region is configured to mitigate oxide fixed charge impact on the plurality of HV diodes.
